(19) United States
(12) Patent Application Publication
(10) Pub. No.: US 2009/0266590 A1
(43) Pub. Date: Oct. 29, 2009

(54) INTERCONNECT STRUCTURE AND METHOD FOR FABRICATING THE SAME

(75) Inventor: Nobuo AOI, Hyogo (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/476,794

(22) Filed: Jun. 2, 2009

Related U.S. Application Data
(63) Continuation of application No. PCT/JP2008/002542, filed on Sep. 16, 2008.

(30) Foreign Application Priority Data
Nov. 6, 2007 (JP) 2007-288491

(51) Int. Cl. H05K 1/09; H05K 3/46

(52) U.S. Cl. 174/257; 427/97.2; 977/752; 174/264

(57) ABSTRACT

An interconnect structure includes: an interlayer insulating film formed on a lower metal layer; a contact hole formed in the interlayer insulating film to expose the lower metal layer; a plurality of carbon nanotubes formed on a bottom of the contact hole; an wiring metal filled in the contact hole to fill gap between the plurality of carbon nanotubes; and an upper wiring formed above the contact hole. A Ti layer is formed between the plurality of carbon nanotubes and the upper wiring.

### BACKGROUND

The present invention relates to an interconnect structure which realizes highly reliable interconnect, and a method for fabricating the same.

A maximum current density at a contact hole of an LSI multilevel interconnect structure is significantly increasing with scaling down in design rules. Therefore, it is conceivable that copper interconnects conventionally used in multilevel interconnect structures cannot achieve required long-life reliability (see, e.g., IEICE TRANS. ELECTRON., Vol. E89-C, No. 11, p. 1499 (2006)). According to ITRS (International Technology Roadmap for Semiconductors), the maximum current density is expected to exceed the order of 1×10⁷ A/cm² in a generation of structures where a half pitch (hp) as a design rule index is 22 nm (commercial node: 16 nm). Since a maximum sustainable current density of Cu is on the order of 1×10⁶ A/cm², the copper interconnects used in the multilevel interconnect structures are approaching their limits.

In this respect, replacement of copper used at the contact hole of the multilevel interconnect structure with carbon nanotube has been proposed (see, e.g., Proc. IEEE 2004 International Interconnect Technology Conference). The carbon nanotube is known as a material which endures a current density on the order of 1×10⁹ A/cm² and allows ballistic transport. Therefore, intensive researches have been made on the carbon nanotube as a candidate for next-generation interconnect materials. The carbon nanotube, which is formed by thermal CVD or plasma CVD using a Co catalyst, is expected to achieve low resistance, high reliability interconnects comparable to or superior to the copper interconnects.

### SUMMARY

However, forming carbon nanotubes in a nanometer order size contact hole at a sufficiently high density, such as on the order of 10¹² nanotubes/cm², is quite difficult. At present, it is confirmed that the carbon nanotubes can be formed at a density on the order of 10¹¹ nanotubes/cm² in the minute contact hole, and that they have a resistance value nearly equal to that of tungsten (see, e.g., IEICE TRANS. ELECTRON., Vol. E89-C, No. 11, p. 1499 (2006)). When only the carbon nanotubes are formed in the contact hole according to a conventional method, a resistance value at the contact hole becomes higher than that when copper is filled in the contact hole. Therefore, power consumption of the LSI may increase. To cope with this problem, there is another proposal to form the carbon nanotubes and metal such as copper together in the contact hole (see, e.g., Published Japanese Patent Application No. 2005-109465). However, when the carbon nanotubes and copper are formed together in the contact hole, a problem of increase in contact resistance arises (see, e.g., MSC2006 Research Conference Proceeding D3).

In view of the foregoing, a goal of the present invention is to provide an interconnect structure which realizes highly reliable interconnect, and a method for fabricating the same.

To reach the above-described goal, the present invention discloses, in one aspect thereof, an interconnect structure including: an interlayer insulating film formed on a lower metal layer; a contact hole formed in the interlayer insulating film to expose the lower metal layer; a plurality of carbon nanotubes formed on a bottom of the contact hole; an wiring metal filled in the contact hole to fill gap between the plurality of carbon nanotubes; and an upper wiring formed above the contact hole, wherein an upper metal layer made of a Ti layer at the bottom of Cu wiring is formed between the plurality of carbon nanotubes and the upper wiring.

The present invention discloses, in one aspect thereof, an interconnect structure further including: a lower metal layer which is made of a Ti layer on Cu wiring and formed on at least the bottom of the contact hole to present between the lower metal layer and bottom ends of the plurality of carbon nanotubes.

The present invention discloses, in one aspect thereof, an interconnect structure, wherein the upper metal layer is formed on at least top ends of the plurality of carbon nanotubes.

The present invention discloses, in one aspect thereof, an interconnect structure, wherein the upper metal layer is connected to at least the top ends of the plurality of carbon nanotubes and covers a bottom surface of the upper wiring.

The present invention discloses, in one aspect thereof, an interconnect structure including: an interlayer insulating film formed on a lower metal layer; a contact hole formed in the interlayer insulating film to expose the lower metal layer; a lower metal layer made of a Ti layer on Cu wiring and formed on at least a bottom of the contact hole; a plurality of carbon nanotubes formed on the lower metal layer on the bottom of the contact hole; and an wiring metal filled in the contact hole to fill gap between the plurality of carbon nanotubes.

The present invention discloses, in one aspect thereof, an interconnect structure, wherein the carbon nanotubes have a multiwall structure.

The present invention discloses, in one aspect thereof, an interconnect structure, wherein the wiring metal is copper.

The present invention discloses, in one aspect thereof, a method for fabricating an interconnect structure including: (a) forming an interlayer insulating film on a lower metal layer; (b) forming a contact hole in the interlayer insulating film to expose the lower metal layer; (c) forming a plurality of carbon nanotubes on a bottom of the contact hole, and filling with a wiring metal in the contact hole to fill gap between the plurality of carbon nanotubes; and (d) forming an upper wiring above the contact hole after the formation (c); wherein an upper metal layer made of a Ti layer at the bottom of Cu wiring is formed between the plurality of carbon nanotubes and the upper wiring.

The present invention discloses, in one aspect thereof, a method for fabricating an interconnect structure further including: (e) forming a lower metal layer made of a Ti layer on Cu wiring on at least the bottom of the contact hole between the forming the contact hole and the forming the plurality of carbon nanotubes and filling with the wiring metal.

The present invention discloses, in one aspect thereof, a method for fabricating an interconnect structure, wherein the forming the plurality of carbon nanotubes and filling with the wiring metal includes: forming the plurality of carbon nanotubes so that top ends thereof do not protrude from the contact hole; forming the upper metal layer on at least top ends of the plurality of carbon nanotubes; and then filling with the wiring metal.

The present invention discloses, in one aspect thereof, a method for fabricating an interconnect structure, wherein the forming the plurality of carbon nanotubes and filling with the wiring metal includes: forming the plurality of carbon nanotubes so that top ends thereof protrude from the contact hole; and then filling with the wiring metal; and the method further includes: (f) removing part of the top ends of the plurality of carbon nanotubes protruding from the contact hole to planarize a top of the contact hole between the forming the plurality of carbon nanotubes and filling with the wiring metal and the forming the upper wiring; and (g) forming the upper metal layer on the contact hole to be connected to the plurality of carbon nanotubes after the removing the part of the top ends of the plurality of carbon nanotubes and the forming the upper wiring.

The present invention discloses, in one aspect thereof, a method for fabricating an interconnect structure including: (a) forming an interlayer insulating film on a lower metal layer; (b) forming a contact hole in the interlayer insulating film to expose the lower metal layer; (c) forming a lower metal layer made of a Ti layer on Cu wiring on at least a bottom of the contact hole; and (d) forming a plurality of carbon nanotubes on the lower metal layer on the bottom of the contact hole, and then filling with an wiring metal in the contact hole to fill gap between the plurality of carbon nanotubes.

The present invention discloses, in one aspect thereof, a method for fabricating an interconnect structure, wherein the carbon nanotubes have a multiwall structure.

The present invention discloses, in one aspect thereof, a method for fabricating an interconnect structure, wherein the wiring metal is copper.

In an interconnect structure including a lower metal layer and an upper wiring connected through a structure constituted of carbon nanotubes and a copper film formed in a contact hole, the Ti layer can be formed between the carbon nanotubes and the upper wiring according to the interconnect structure of the present invention and the method for fabricating the same. Therefore, increase in contact resistance to the upper wiring can be suppressed. Further, since the Ti layer is formed between the carbon nanotubes and the lower metal layer, increase in contact resistance to the lower metal layer can be suppressed.

As described above, the present invention is useful for fabricating high reliability, low resistance metal interconnects.

### BRIEF DESCRIPTION OF THE DRAWINGS

FIGS. 1A to 1D are cross-sectional views sequentially illustrating processes of a method for fabricating an interconnect structure according to Embodiment 1 of the present invention.

FIGS. 2A to 2C are cross-sectional views sequentially illustrating processes of the method for fabricating the interconnect structure according to Embodiment 1 of the present invention.

FIGS. 3A to 3C are cross-sectional views sequentially illustrating processes of the method for fabricating the interconnect structure according to Embodiment 1 of the present invention.

FIGS. 4A to 4D are cross-sectional views sequentially illustrating processes of a method for fabricating an interconnect structure according to Embodiment 2 of the present invention.

FIGS. 5A to 5C are cross-sectional views sequentially illustrating processes of the method for fabricating the interconnect structure according to Embodiment 2 of the present invention.

FIGS. 6A to 6C are cross-sectional views sequentially illustrating processes of the method for fabricating the interconnect structure according to Embodiment 2 of the present invention.

### DETAILED DESCRIPTION

### EMBODIMENT 1

Hereinafter, an interconnect structure according to Embodiment 1 of the present invention and a method for fabricating the same will be described with reference to the accompanying drawings.

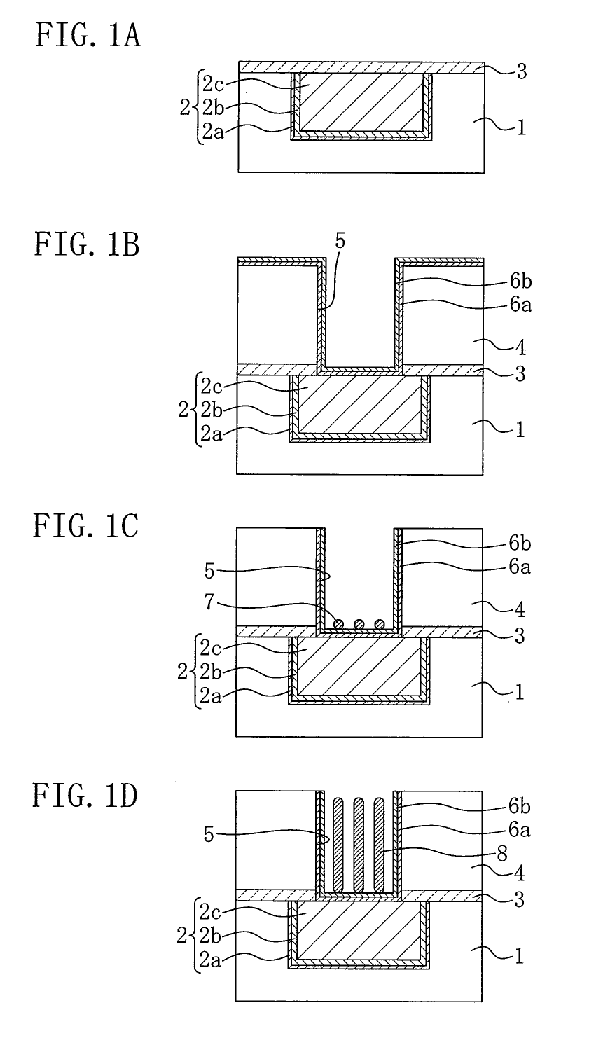

FIGS. 1A to 1D, 2A to 2C, and 3A to 3C are cross-sectional views sequentially illustrating processes of a method for fabricating an interconnect structure according to Embodiment 1 of the present invention.

First, as shown in FIG. 1A, a lower wiring groove is formed by general photolithography and etching in an insulating film 1 which is made of a silicon oxide film, for example, and formed on a silicon substrate (not shown), for example. Then, a barrier metal film 2a made of a tantalum nitride film, for example, and a barrier metal film 2b made of a tantalum film, for example, are deposited in this order on a sidewall surface and a bottom surface of the lower wiring groove formed in the insulating film 1. On the barrier metal film 2b, a seed layer (not shown) is deposited, and a copper film 2c is deposited by electroplating. Part of the layers existing outside the lower wiring groove is polished away by CMP for surface planarization. Thus, a lower metal layer structure 2 constituted of the barrier metal film 2a, the barrier metal film 2b, and the copper film 2c is formed. Subsequently, a barrier insulating film 3 made of a SiCN film, for example, is deposited on the insulating film 1 and the lower metal layer structure 2.

Then, as shown in FIG. 1B, an interlayer insulating film 4 made of a 200 nm thick SiOC film, for example, is deposited on the barrier insulating film 3 by CVD. Then, a contact hole 5 is formed in the interlayer insulating film 4 and the barrier insulating film 3 by general photolithography and etching, so that the contact hole 5 penetrates the interlayer insulating film 4 and the barrier insulating film 3 and exposes a top surface of the lower metal layer structure 2. Subsequently, a TiN film 6a of 10 nm in thickness, for example, and a Ti layer 6b of 10 nm in thickness, for example, are formed in this order on a sidewall surface and a bottom surface of the contact hole 5, and a top surface of the interlayer insulating film 4.

Then, as shown in FIG. 1C, a thin Co film is formed on the whole surface of the Ti layer 6b, and then parts of the thin Co film, the Ti layer 6b, and the TiN film 6a which are present outside the contact hole 5 are polished away by CMP. Then, the thin Co film remaining in the contact hole 5 is aggregated by thermal treatment into Co particulates 7.

Then, as shown in FIG. 1D, using the Co particulates 7 as a catalyst, multiwall carbon nanotubes 8 are formed in the contact hole 5 by thermal CVD. In this process, the carbon nanotubes 8 are formed to become shorter than the thickness of the interlayer insulating film 4 (so that they do not protrude from the contact hole 5).

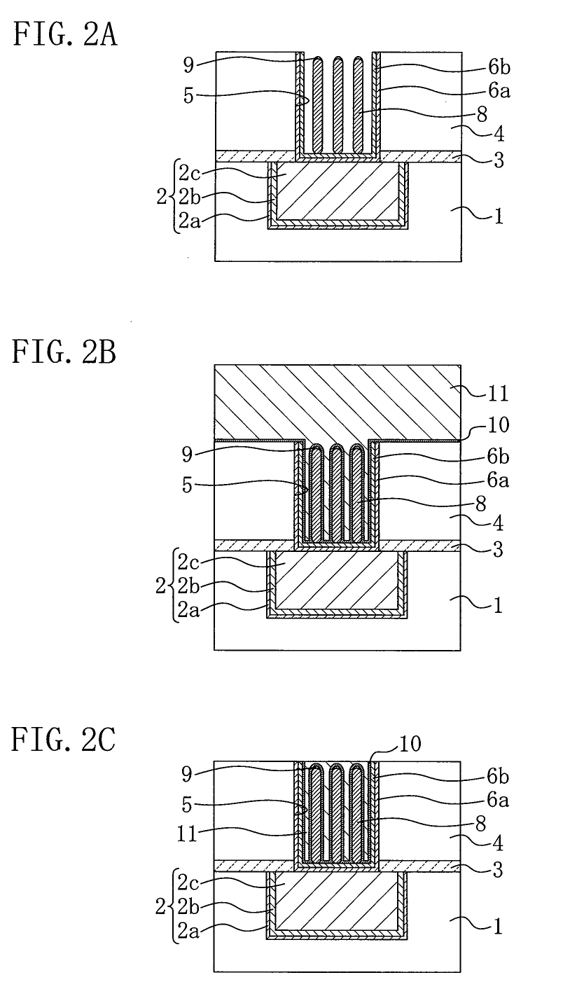

Then, as shown in FIG. 2A, a Ti layer 9 of 4 nm in thickness, for example, is formed to cover at least top ends of the carbon nanotubes 8.

Then, as shown in FIG. 2B, a copper seed layer 10 of 10 nm in thickness, for example, is formed by sputtering to cover the top surface of the interlayer insulating film 4, the sidewall and bottom surfaces of the contact hole 5, the surfaces of the carbon nanotubes 8, and the surface of the Ti layer 9. Further, a copper film 11 is deposited by electroplating to fill the contact hole 5.

Then, as shown in FIG. 2C, part of the copper film 11 (including the copper seed film 10) present on the interlayer insulating film 4 and outside the contact hole 5 is polished away by CMP.

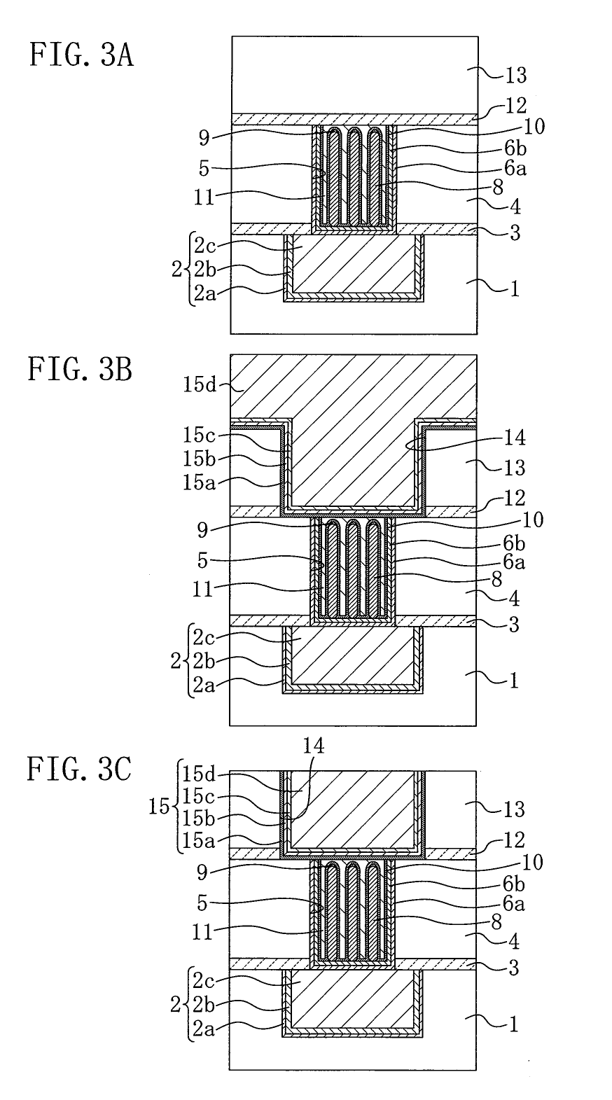

Then, as shown in FIG. 3A, a barrier insulating film 12 made of an SiCN film, for example, is formed to cover the interlayer insulating film 4 and the contact hole 5. Then, an interlayer insulating film 13 made of a 200 nm thick SiOC film, for example, is deposited on the barrier insulating film 12 by CVD.

Then, as shown in FIG. 3B, an upper wiring groove 14 is formed in the interlayer insulating film 13 and the barrier insulating film 12 by general photolithography and etching, so that the upper wiring groove 14 penetrates the interlayer insulating film 13 and the barrier insulating film 12 and exposes a top surface of the copper film 11 in the contact hole 5. Subsequently, a barrier metal film 15a made of a tantalum nitride film, for example, and a barrier metal film 15b made of a tantalum film, for example, are formed in this order on a sidewall surface and a bottom surface of the upper wiring groove 14, and a top surface of the interlayer insulating film 13. Then, a copper seed layer 15c of 10 nm in thickness, for example, is formed on the barrier metal film 15b, and a copper film 15d is deposited by electroplating to fill the upper wiring groove 14.

Then, as shown in FIG. 3C, part of the layers present outside the upper wiring groove 14 is polished away by CMP for surface planarization. Thus, an upper interconnect structure 15 constituted of the barrier metal film 15a, the barrier metal film 15b, the copper seed layer 15c, and the copper film 15d is formed.

As described above, in the interconnect structure including the lower metal layer and the upper wiring connected through a structure constituted of the carbon nanotubes 8 and the copper film 11 formed in the contact hole 5, the Ti layer 9 can be formed on the top ends of the carbon nanotubes 8 according to the interconnect structure and the fabrication method of the present embodiment. Therefore, increase in contact resistance to the upper wiring can be suppressed. Further, since the Ti layer 6b is connected to the bottom ends of the carbon nanotubes 8, increase in contact resistance to the lower metal layer can be suppressed.

Since the carbon nanotubes 8 and the copper film 11 coexist in the contact hole 5, reduction in resistance and improvement in reliability of the contact hole 5 can be both achieved even when the carbon nanotubes 8 are formed at a low density. Specifically, the resistance of the contact hole 5 is parallel resistance constituted of resistance of the copper film and resistance of the carbon nanotubes 8, and the carbon nanotubes 8 allow ballistic transport. Therefore, the coexistence of the copper film and the carbon nanotubes 8 in the contact hole 5 allows further reduction in resistance of the contact hole 5 as compared with the case where only the copper film is formed in the contact hole 5. Moreover, the carbon nanotubes 8 present in the contact hole 5 remain in the contact hole 5 even when copper migration occurs. Therefore, breaking of metal wire at the contact hole 5 can significantly be suppressed.

In the above-described embodiment, Co is used as a catalyst metal for forming the carbon nanotubes. However, other metals such as Ni and Fe can also be used. Further, copper used as the interconnect material may be replaced with aluminum, silver, or gold.

In the interconnect structure of the above-described embodiment, the barrier metal film 6b made of the Ti layer is formed below the carbon nanotubes 8, and the Ti layer 9 is formed on the top ends of the carbon nanotubes 8. However, from a viewpoint of suppressing the increase in contact resistance at the contact hole 5, it is needless to say that the Ti layer is formed on at least one of the top ends and the bottom ends of the carbon nanotubes 8.

### EMBODIMENT 2

Hereinafter, an interconnect structure according to Embodiment 2 of the present invention and a method for fabricating the same will be described with reference to the accompanying drawings.

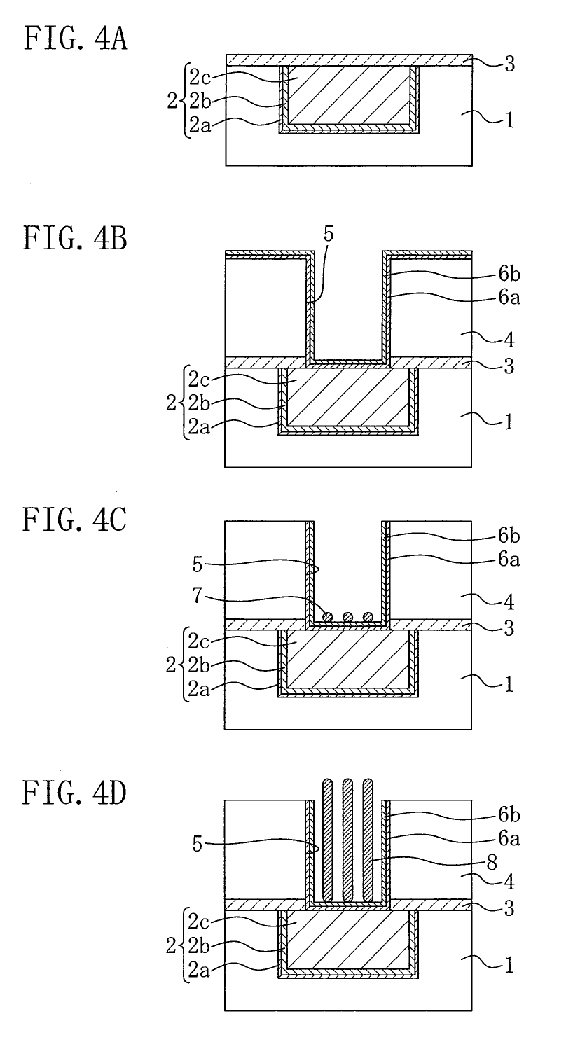

FIGS. 4A to 4D, 5A to 5C, and 6A to 6C are cross-sectional views sequentially illustrating processes of a method for fabricating an interconnect structure according to Embodiment 2 of the present invention.

First, as shown in FIG. 4A, a lower wiring groove is formed by general photolithography and etching in an insulating film 1 which is made of a silicon oxide film, for example, and formed on a silicon substrate (not shown), for example. Then, a barrier metal film 2a made of a tantalum nitride film, for example, and a barrier metal film 2b made of a tantalum film, for example, are deposited in this order on a sidewall surface and a bottom surface of the lower wiring groove formed in the insulating film 1. On the barrier metal film 2b, a seed layer (not shown) is deposited, and a copper film 2c is deposited by electroplating. Part of the layers present outside the lower wiring groove is polished away by CMP for surface planarization. Thus, a lower metal layer structure 2 constituted of the barrier metal film 2a, the barrier metal film 2b, and the copper film 2c is formed. Subsequently, a barrier insulating film 3 made of a SiCN film, for example, is deposited on the insulating film 1 and the lower metal layer structure 2.

Then, as shown in FIG. 4B, an interlayer insulating film 4 made of a 200 nm thick SiOC film, for example, is deposited on the barrier insulating film 3 by CVD. Then, a contact hole 5 is formed in the interlayer insulating film 4 and the barrier insulating film 3 by general photolithography and etching, so that the contact hole 5 penetrates the interlayer insulating film 4 and the barrier insulating film 3 and exposes a top surface of the lower metal layer structure 2. Subsequently, a TiN film 6a of 10 nm in thickness, for example, and a Ti layer 6b of 10 nm in thickness, for example, are formed in this order on a sidewall surface and a bottom surface of the contact hole 5, and a top surface of the interlayer insulating film 4.

Then, as shown in FIG. 4C, a thin Co film is formed on the whole surface of the Ti layer 6b, and then parts of the thin Co film, the Ti layer 6b and the TiN film 6a which are present outside the contact hole 5 are polished away by CMP. Then, the thin Co film remaining in the contact hole 5 is aggregated by thermal treatment into Co particulates 7.

Then, as shown in FIG. 4D, using the Co particulates 7 as a catalyst, multiwall carbon nanotubes 8 are formed in the contact hole 5 by thermal CVD. In this process, the carbon nanotubes 8 are formed to become longer than the thickness of the interlayer insulating film 4 (so that they protrude from the contact hole 5).

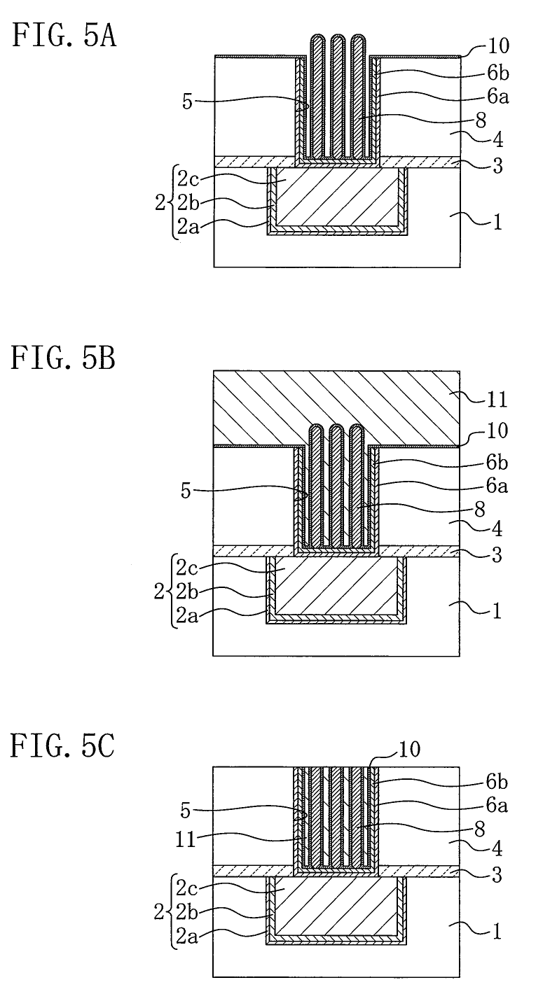

Then, as shown in FIG. 5A, a copper seed layer 10 of 10 nm in thickness, for example, is formed by sputtering to cover the top surface of the interlayer insulating film 4, the sidewall and bottom surfaces of the contact hole 5, and the surfaces of the carbon nanotubes 8.

Then, a copper film 11 is deposited by electroplating to fill the contact hole 5 as shown in FIG. 5B.

Then, as shown in FIG. 5C, part of the copper film 11 (including the copper seed film 10) present on the interlayer insulating film 4 and outside the contact hole 5 is polished away by CMP for surface planarization.

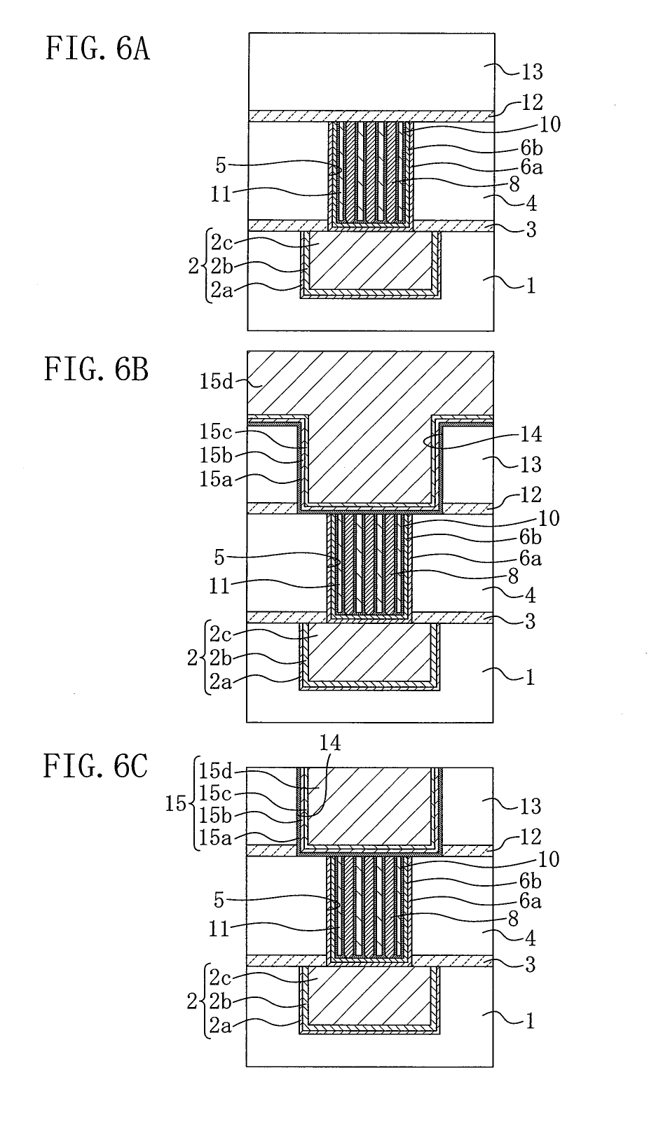

Then, as shown in FIG. 6A, a barrier insulating film 12 made of an SiCN film, for example, is formed to cover the interlayer insulating film 4 and the contact hole 5. Then, an interlayer insulating film 13 made of a 200 nm thick SiOC film, for example, is deposited on the barrier insulating film 12 by CVD.

Then, as shown in FIG. 6B, an upper wiring groove 14 is formed in the interlayer insulating film 13 and the barrier insulating film 12 by general photolithography and etching, so that the upper wiring groove 14 penetrates the interlayer insulating film 13 and the barrier insulating film 12 and exposes a top surface of the copper film 11 and top surfaces of the carbon nanotubes 8 in the contact hole 5. Subsequently, a barrier metal film 15a made of a 5 nm thick Ti layer, for example, is formed on a sidewall surface and a bottom surface of the upper wiring groove 14, and a top surface of the interlayer insulating film 13. Further, a barrier metal film 15b made of a tantalum film, for example, is formed on the barrier metal film 15a. Then, a copper seed layer 15c of 10 nm in thickness, for example, is formed on the barrier metal film 15b, and a copper film 15d is deposited by electroplating to fill the upper wiring groove 14.

Then, as shown in FIG. 6C, part of the layers present outside the upper wiring groove 14 is polished away by CMP for surface planarization. Thus, an upper interconnect structure 15 constituted of the barrier metal film 15a, the barrier metal film 15b, the copper seed layer 15c, and the copper film 15d is formed.

As described above, in the interconnect structure including the lower metal layer and the upper wiring connected through a structure constituted of the carbon nanotubes 8 and the copper film 11 formed in the contact hole 5, the barrier metal film 15a made of the Ti layer can be connected to the top ends of the carbon nanotubes 8 according to the interconnect structure and the fabrication method of the present embodiment. Therefore, increase in contact resistance to the upper wiring can be suppressed. Further, since the Ti layer 6b is connected to the bottom ends of the carbon nanotubes 8, increase in contact resistance to the lower wiring can be suppressed.

Since the carbon nanotubes 8 and the copper film 11 coexist in the contact hole 5, reduction in resistance and improvement in reliability of the contact hole 5 can be both achieved even when the carbon nanotubes 8 are formed at a low density. Specifically, the resistance of the contact hole 5 is parallel resistance constituted of resistance of the copper film and resistance of the carbon nanotubes 8, and the carbon nanotubes 8 allow ballistic transport. Therefore, the coexistence of the copper film and the carbon nanotubes 8 in the contact hole 5 allows further reduction in resistance of the contact hole 5 as compared with the case where only the copper film is formed in the contact hole 5. Moreover, the carbon nanotubes 8 present in the contact hole 5 remain in the contact hole 5 even when copper migration occurs. Therefore, breaking of metal wire at the contact hole 5 can significantly be suppressed.

In the above-described embodiment, Co is used as a catalyst metal for forming the carbon nanotubes. However, other metals such as Ni and Fe can also be used. Further, copper used as the interconnect material may be replaced with aluminum, silver, or gold.

In the interconnect structure of the above-described embodiment, the barrier metal film 6b made of the Ti layer is formed below the carbon nanotubes 8, and the barrier metal film 15a made of the Ti layer is formed on the top ends of the carbon nanotubes 8. However, from a viewpoint of suppressing the increase in contact resistance, it is needless to say that the Ti layer is formed on at least one of the top ends and the bottom ends of the carbon nanotubes 8.

As described above, the present invention is useful for fabricating high reliability, low resistance metal interconnects.

1. An interconnect structure comprising:
an interlayer insulating film formed on a lower metal layer;
a contact hole formed in the interlayer insulating film to expose the lower metal layer;
a plurality of carbon nanotubes formed on a bottom of the contact hole;
an wiring metal filled in the contact hole to fill gap between the plurality of carbon nanotubes; and
an upper wiring formed above the contact hole, wherein
an upper metal layer made of a Ti layer at the bottom of Cu wiring is formed between the plurality of carbon nanotubes and the upper wiring.

2. The interconnect structure of claim 1, further comprising:
a lower metal layer which is made of a Ti layer and formed on at least the bottom of the contact hole to present between the lower metal layer and bottom ends of the plurality of carbon nanotubes.

3. The interconnect structure of claim 1, wherein the upper metal layer is formed on at least top ends of the plurality of carbon nanotubes.

4. The interconnect structure of claim 1, wherein
the upper metal layer is connected to at least the top ends of the plurality of carbon nanotubes and covers a bottom surface of the upper wiring.

5. An interconnect structure comprising:
an interlayer insulating film formed on a lower metal layer;
a contact hole formed in the interlayer insulating film to expose the lower metal layer;
a lower metal layer made of a Ti layer on Cu wiring and formed on at least a bottom of the contact hole;
a plurality of carbon nanotubes formed on the lower metal layer on the bottom of the contact hole; and
an wiring metal filled in the contact hole to fill gap between the plurality of carbon nanotubes.

6. The interconnect structure of claim 1, wherein
the carbon nanotubes have a multiwall structure.

7. The interconnect structure of claim 1, wherein
the wiring metal is copper.

8. A method for fabricating an interconnect structure comprising:
(a) forming an interlayer insulating film on a lower metal layer;
(b) forming a contact hole in the interlayer insulating film to expose the lower metal layer;
(c) forming a plurality of carbon nanotubes on a bottom of the contact hole, and filling with an wiring metal in the contact hole to fill gap between the plurality of carbon nanotubes; and
(d) forming an upper wiring above the contact hole after the formation (c); wherein
an upper metal layer made of a Ti layer at the bottom of Cu wiring is formed between the plurality of carbon nanotubes and the upper wiring.

9. The method of claim 8, further comprising:
(e) forming a lower metal layer made of a Ti layer on Cu wiring on at least the bottom of the contact hole between the forming the contact hole and the forming the plurality of carbon nanotubes and filling with the wiring metal.

10. The method of claim 8, wherein
the forming the plurality of carbon nanotubes and filling with the wiring metal includes: forming the plurality of carbon nanotubes so that top ends thereof do not protrude from the contact hole; forming the upper metal layer on at least top ends of the plurality of carbon nanotubes; and then filling with the wiring metal.

11. The method of claim 8, wherein
the forming the plurality of carbon nanotubes and filling with the wiring metal includes: forming the plurality of carbon nanotubes so that top ends thereof protrude from the contact hole; and then filling with the wiring metal; and
the method further comprising:
(f) removing part of the top ends of the plurality of carbon nanotubes protruding from the contact hole to planarize a top of the contact hole between the forming the plurality of carbon nanotubes and filling with the wiring metal and the forming the upper wiring; and
(g) forming the upper metal layer on the contact hole to be connected to the plurality of carbon nanotubes after the removing the part of the top ends of the plurality of carbon nanotubes and the forming the upper wiring.

12. A method for fabricating an interconnect structure comprising:
(a) forming an interlayer insulating film on a lower metal layer;
(b) forming a contact hole in the interlayer insulating film to expose the lower metal layer;
(c) forming a lower metal layer made of a Ti layer on Cu wiring on at least a bottom of the contact hole; and
(d) forming a plurality of carbon nanotubes on the lower metal layer on the bottom of the contact hole, and then filling with an wiring metal in the contact hole to fill gap between the plurality of carbon nanotubes.

13. The method of claim 8, wherein
the carbon nanotubes have a multiwall structure.

14. The method of claim 8, wherein
the wiring metal is copper.

15. The interconnect structure of claim 2, wherein the upper metal layer is formed on at least top ends of the plurality of carbon nanotubes.

16. The interconnect structure of claim 2, wherein
the upper metal layer is connected to at least the top ends of the plurality of carbon nanotubes and covers a bottom surface of the upper wiring.

17. The method of claim 9, wherein
the forming the plurality of carbon nanotubes and filling with the wiring metal includes: forming the plurality of carbon nanotubes so that top ends thereof do not protrude from the contact hole; forming the upper metal layer on at least top ends of the plurality of carbon nanotubes; and then filling with the wiring metal.

18. The method of claim 9, wherein
the forming the plurality of carbon nanotubes and filling with the wiring metal includes: forming the plurality of carbon nanotubes so that top ends thereof protrude from the contact hole; and then filling with the wiring metal; and
the method further comprising:
(f) removing part of the top ends of the plurality of carbon nanotubes protruding from the contact hole to planarize a top of the contact hole between the forming the plurality of carbon nanotubes and filling with the wiring metal and the forming the upper wiring; and
(g) forming the upper metal layer on the contact hole to be connected to the plurality of carbon nanotubes after the removing the part of the top ends of the plurality of carbon nanotubes and the forming the upper wiring.
